(19) United States
(12) Patent Application Publication
(10) Pub. No.: US 2005/0229849 A1
(43) Pub. Date: Oct. 20, 2005

(54) High productivity plasma processing chamber

(75) Inventors: Mario David Silvetti, Morgan Hill, CA (US); David H. Quach, San Jose, CA (US); Bok Hoen Kim, San Jose, CA (US); Thomas Nowak, Cupertino, CA (US); Thomas K. Cho, Palo Alto, CA (US); Fred H. Hariz, Fremont, CA (US); Robert B. Moore, Livermore, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(73) Assignee: APPLIED MATERIALS, INC.

(21) Appl. No.: 11/057,041

(22) Filed: Feb. 11, 2005

Related U.S. Application Data
(60) Provisional application No. 60/544,574, filed on Feb. 13, 2004.

(51) Int. Cl. C23C 16/00

(52) U.S. Cl. 118/715; 156/345.37; 118/725; 427/248.1

(57) ABSTRACT

Embodiments of the present invention are generally directed to apparatus and methods for a plasma-processing chamber requiring less maintenance and downtime and possessing improved reliability over the prior art. In one embodiment, the apparatus includes a substrate support resting on a ceramic shaft, an inner shaft allowing for electrical connections to the substrate support at atmospheric pressure, an aluminum substrate support resting on but not fixed to a ceramic support structure, sapphire rest points swaged into the substrate support, and a heating element inside the substrate support arranged in an Archimedes spiral to reduce warping of the substrate support and to increase its lifetime. Methods include increasing time between in-situ cleans of the chamber by reducing particle generation from chamber surfaces. Reduced particle generation occurs via temperature control of chamber components and pressurization of non-processing regions of the chamber relative to the processing region with a purge gas.

### CROSS-REFERENCE TO RELATED APPLICATIONS

This application claims benefit of U.S. provisional patent application Ser. No. 60/544,574, filed Feb. 13, 2004, which is herein incorporated by reference.

### BACKGROUND OF THE INVENTION

1. Field of the Invention

Embodiments of the present invention generally relate to a semiconductor device or flat panel display processing chamber.

2. Description of the Related Art

Due to competitive pressures to reduce device cost in the semiconductor and flat panel device fabrication industries, the need for both improved device yields and reduced processing chamber downtime i.e., the time that a chamber is unavailable for processing, has become important. However, the increasingly stringent substrate-processing requirements that improve semiconductor device yield often lead to more downtime. This is due in part to the narrow acceptable range of process variation for a chamber during operation. To monitor different aspects of process chamber performance, a number of different test substrates or “process monitors” are treated periodically by a given process chamber to confirm that the chamber is operating as required, i.e., the process is “in control”. Typical process monitors for a substrate-processing chamber include uniformity of thickness of a deposited film, edge exclusion of the deposited film, number of defects detected greater than a specified size, etc. If a process monitor indicates problems with a processing chamber, for example, particle counts per substrate have increased beyond a maximum allowable level, the substrate-processing chamber is considered “out of control”. Whenever any process monitor for a chamber is determined to be out of control, the chamber must be taken off-line and the problem corrected. The smaller the allowable range for a given process monitor, the more often this occurs. Also contributing to chamber downtime is the shortened lifetime of critical chamber components. This is brought about by outright failure of the components or simply their inability to function as required after prolonged use in the severe environment of a process chamber. Repeated exposure to high temperatures and highly reactive process chemicals can alter a component's critical dimensions through deformation or erosion, or,cause it to fail catastrophically. Even minor warping or other changes in the shape of some process chamber components can have a serious effect on the uniformity of a deposited film on a substrate.

One key process monitor is the number of allowable defects—often particles—on a substrate that is being processed in a semiconductor processing chamber. High particle counts detected on substrates result in additional chamber downtime while the cause is determined and corrected. A common particle source in semiconductor device fabrication processing chambers is the growth of unwanted processing byproducts, which deposit on or chemically attack (i.e., corroding or pitting) plasma processing chamber components. Over time, the deposited byproducts or the corroded or pitted chamber surfaces tend to release particles, resulting in particle defects on substrates being processed in the chamber. This is particularly true where high-pressure plasma processes or high plasma powers are utilized during the semiconductor fabrication process; the processing gases and/or generated plasma are more prone to leak out of the processing region of the chamber and form deposits. Also, these deposits are much more likely-to flake off or generate particles when the surface they are deposited on is subject to large oscillations in temperature.

To prevent attack of the semiconductor chamber components by aggressive processing chemistries and/or ion bombardment from plasma generated in chemical vapor deposition (CVD), plasma vapor deposition (PVD), and plasma etch processing chambers, all exposed components either consist of or are coated with materials that will not be damaged or eroded during processing or cleaning steps. Ceramic materials such as alumina (amorphous Al₂O₃) are used to prevent attack by the chemistries and plasma environment. In situations where it is impractical or impossible to manufacture process chamber components from such materials (e.g., chamber walls, vacuum bellows, etc.), removable or replaceable shielding is often incorporated into the design of the substrate-processing chamber to protect these components. But adding components inside a processing chamber has drawbacks, increasing chamber cost and internal surface area. Greater surface area in a processing chamber lengthens chamber pump-down time prior to processing, increasing process chamber downtime. Also, while shielding does protect a chamber's internal components from reactive process gases and deposits, it does not prevent the accumulation of process products on the shielding itself. Therefore, deposits of process byproducts will still be a source of particle contamination in the processing chamber.

Whenever a chamber's process monitor for particle counts exceeds a desired value due to problems related to the attack or deposition of processing byproducts, it is common to perform an in-situ chamber clean. The length of the in-situ clean process is directly related to the thickness and surface area of the deposited materials being removed. However, the in-situ chamber clean is conducted as infrequently as possible since it prevents devices from being processed and therefore is defined as downtime. Hence, the frequency and length of the in-situ chamber clean process are often minimized.

Another contributor to chamber downtime is replacement of process chamber components due to wear and tear or because of unexpected failures of the components. One component that is subject to failure is the heater assembly of plasma-processing chamber as well as many of this assembly's constituent parts. In addition to being a relatively expensive component, a heater assembly is time consuming to replace, so any increase in its reliability will positively impact chamber down-time. Such an assembly generally consists of a heater pedestal, a heating element or elements arranged inside a cavity in the heater pedestal, a pedestal temperature sensor and an RF bias feed—also arranged inside the heater pedestal—and a supporting shaft fixed to the bottom of the pedestal. Elements of the heater assembly subject to failure or deformation through use are the heater pedestal, the heater element inside the heater pedestal, electrical feed-throughs into the heater pedestal and the substrate receiving surface on the face of the heater pedestal.

The primary purpose of the pedestal is to support the substrate. The heater is provided to heat the pedestal and therefore to heat the substrate. For high device yield it is critical for the substrate to be heated uniformly when processed in the chamber. Aluminum heater pedestals provide high heating and plasma uniformity and greater heater element reliability, but are prone to deformation that ultimately reduces uniformity; at process temperatures aluminum is not strong enough to remain completely rigid and over time pedestals sag and warp. Also, the non-uniform arrangement of the heater elements inside the pedestal creates hotter and cooler regions, causing warping of the pedestal. Ceramic heater pedestals are rigid at process temperatures, but have higher cost and provide poor heating and plasma uniformity relative to aluminum heaters. Thermal expansion of some components of the heater assembly can also encourage warping of the pedestal if it is constrained incorrectly. For example, the long support shaft fixed to the bottom of the heater pedestal can force the pedestal upward when at process temperature. Also, the heater pedestal itself will expand and contract radially during processing of substrates.

The heater element inside the heater pedestal can also fail over time FIG. 5 schematically represents a plan view of a typical arrangement of heating elements 202 and 203 inside a typical heater pedestal 201. Heating element 202 enters pedestal 201 at feed-through 202a and exits at feed-through 202b. Heating element 203 enters pedestal 201 at feed-through 203a and exits at feed-through 203b. Heating elements 202 and 203 are arranged to maximize the uniformity of heating of pedestal 201. However, significant thermal expansion and contraction of elements 202 and 203 result whenever a process is run in the, chamber since heating of the pedestal is cycled on and off with each wafer. Mechanical fatigue of such heating elements at the feed-through point is a common failure mechanism for pedestal heaters. Additionally, regions of reduced heating that lead to warping of the heater pedestal are also illustrated in FIG. 5. Region 206 is one “cold spot” and 207—the region surrounding the feed-throughs 202a, 202b, 203a, and 203b—is another. Region 207 is a “cold spot” because electrical heating elements generate less heat at their point of penetration into the heater pedestal. For mechanical strength, the heater element's wiring is a larger diameter at this point than inside the remainder of the heating element. The reduced resistance of the larger wire results in much less heat generated by this part of the heating element.

The heater pedestal of a plasma-processing chamber generally has a number of electrical connections that feed into it from below, including power for heating elements and wiring for temperature sensors and RF bias. Since the pedestal is generally located inside the processing chamber, the entire bottom surface of the heater pedestal is typically at vacuum. This requires a vacuum-tight seal where the required electrical connections enter the pedestal. This seal must be strong, non-conductive, heat resistant, and vacuum compatible at high temperatures. When the vacuum seal for the electrical connections is in close proximity to the heater, finding a material that reliably meets the above requirements for such a seal is problematic.

For better heating uniformity, a substrate typically does not rest directly on the surface of a heater pedestal. Because neither the substrate nor the pedestal surface can be manufactured to be perfectly flat, the substrate will only contact the surface of the pedestal at a few discrete points, therefore undergoing uneven heating. Instead a plurality of rest points or other features are fixed to or machined out of the surface of the pedestal, resulting in the substrate being raised slightly above the surface of the pedestal during plasma processing. These rest points or features on the face of the heater pedestal are subject to wear after large numbers of substrates have been processed on the heater pedestal. Replaceable—and therefore removable—rest points can be used, but add significant complexity to the design of the pedestal. Threaded fasteners introduce the potential for creating dead volumes inside the plasma-processing chamber. Removable rest points threaded into the surface of the pedestal may also create additional sources of warp-inducing thermal stresses on the surface of the heater pedestal if the material of the rest points possesses a different coefficient of thermal expansion than the material of the pedestal itself.

Therefore, there is a need for an improved semiconductor processing chamber apparatus and method for reducing or preventing the attack of the process components, for reducing chamber down time, and improving the reliability and reducing the cost of the process chamber components and consumables.

### SUMMARY OF THE INVENTION

The present invention generally includes apparatus and methods for a plasma-processing chamber requiring less maintenance and chamber downtime and possessing improved reliability over the prior art.

The present invention includes apparatus and methods for maximizing the allowable time between in-situ cleans of a plasma processing chamber by reducing the rate at which process products accumulate onto or attack surfaces inside the chamber. The apparatus includes a reduced gap between the process chamber and the substrate support to minimize entry of process products into the lower chamber and subsequent deposition on chamber surfaces. The apparatus further includes temperature control systems for the showerhead—both heating and cooling—to minimize temperature fluctuations and a heating system for the chamber body to ameliorate unwanted deposition of process products in the lower chamber. The apparatus further includes an insert between the chamber lid support and isolator for better thermal isolation of the isolator as well as reducing temperature gradients inside the isolator. The methods include controlling the temperature of the showerhead and chamber walls to constant, optimal temperatures. The methods also include pressurizing the lower chamber with a purge gas to prevent entry of process products.

The present invention also includes an improved heater assembly for plasma processing. The improved heater assembly includes a hybrid aluminum/ceramic heater pedestal. The heater assembly also includes a two-walled support shaft, The heater assembly further includes a single penetration electrical feed-though for the heating element inside the pedestal. The heating element is configured in an Archimedes' spiral inside the heater. A downward force is applied with spring tension to the inner support shaft fixed to the center of the heater pedestal. This force counteracts the upward force on the center of the pedestal resulting from vacuum on the top of the pedestal and atmospheric pressure on the bottom. The invention further includes sapphire balls swaged onto the supporting surface of the heater pedestal as rest points.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a perspective view of a single wafer plasma-processing chamber incorporating an embodiment of the invention, with upper assembly removed for clarity.

FIG. 2 shows a vertical cross-sectional view of the plasma-processing chamber of FIG. 1, taken at line 2-2 of FIG. 1.

FIG. 3 shows an enlarged partial cross-sectional view of the plasma-processing chamber of FIG. 1, taken at line 2-2 of FIG. 1.

FIG. 4 shows a schematic cross-sectional view of the plasma-processing chamber of FIG. 1.

FIG. 5 shows a schematic plan view of a prior art arrangement of heating elements inside a heater pedestal.

FIG. 6 shows a schematic vertical cross-sectional view of a heater assembly for the plasma-processing chamber of FIG. 1, approximately taken at line 2-2 of FIG. 1.

FIG. 7 schematically shows an enlarged cross-sectional view of one embodiment of a heater pedestal with a substrate resting on the heater pedestal.

FIG. 8 shows an enlarged cross-sectional perspective view of one embodiment of a heater pedestal detailing a lift pin through-hole and heater pedestal alignment feature.

FIG. 9 shows a plan view of one embodiment of a heater pedestal.

FIG. 10 schematically shows a perspective view of one embodiment of a ceramic support and one of a plurality of radially oriented alignment slots.

FIG. 11 schematically shows a vertical perspective view of one embodiment of a lift finger.

FIG. 12a schematically shows a dual filament tubular heating element.

FIG. 12b schematically shows a prior art single filament tubular heating element.

FIG. 13 illustrates one example of an Archimedes spiral.

FIG. 14 schematically shows a partial vertical cross-sectional view of a heater assembly for the plasma-processing chamber of FIG. 1, approximately taken at line 2-2 of FIG. 1.

### DETAILED DESCRIPTION

Embodiments of the present invention generally relate to apparatus and methods for an improved semiconductor plasma-processing chamber.

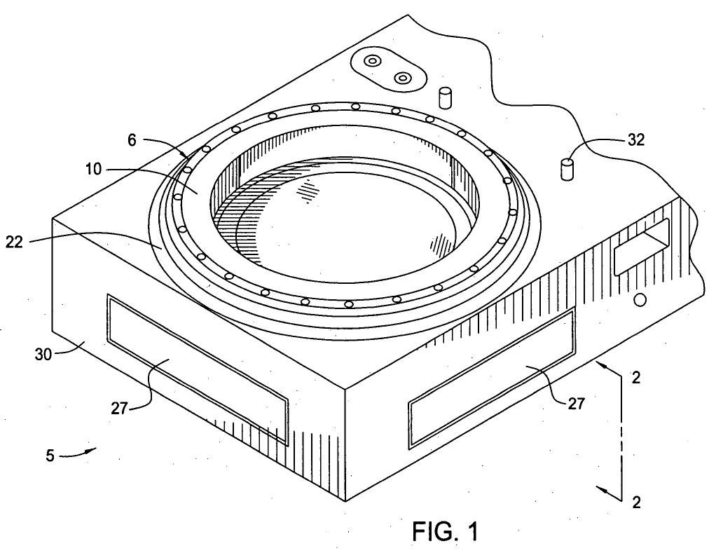

FIG. 1 illustrates a single substrate plasma-processing chamber 5, which incorporates an embodiment of the present invention. The top assembly typical of such a chamber is not shown for clarity. The top assembly includes RF source, gas distribution assembly, gas boxes, and remote plasma source.

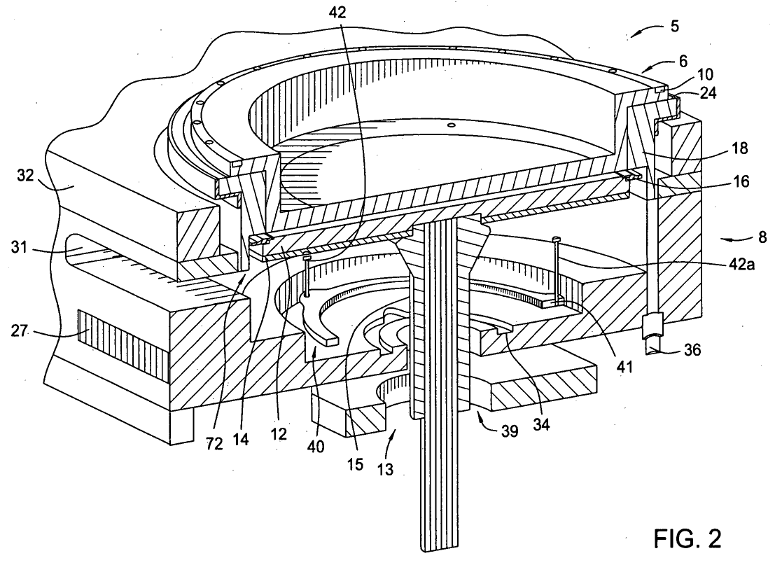

The chamber body 30 of plasma-processing chamber 5 is attached to a mainframe (not shown) that contains a wafer transport system (not shown) and system supporting hardware (not shown). The mainframe and system supporting hardware are designed to transfer the substrate under vacuum from one area of the substrate processing system, deliver the substrate to plasma-processing chamber 5 and remove the substrate when the process steps in plasma-processing chamber 5 are complete. A slit valve opening 31 (see FIG. 2) is provided for passing a substrate from the mainframe to plasma-processing chamber 5 while under vacuum. A slit valve door (not shown) is adapted to seal the plasma-processing chamber. 5 from the mainframe by forming a seal against a sealing surface 32. In one embodiment, plasma-processing chamber 5 is incorporated into a substrate processing apparatus adapted for single substrate processing. In another embodiment, plasma-processing chamber 5 is one of a pair of processing chambers incorporated into a substrate processing apparatus which is adapted to process dual substrates simultaneously.

Plasma-processing chamber 5 may be incorporated in the Producer® Reactor, which is commercially available from Applied Materials, Inc. of Santa Clara, Calif. Plasma-processing chamber 5 is described in detail in commonly assigned U.S. Pat. No. 6,495,233, issued Dec. 17, 2002, filed Jul. 05, 2000 and entitled “APPARATUS FOR DISTRIBUTING GASES IN A CHEMICAL VAPOR DEPOSITION SYSTEM”, which is incorporated herein by reference. The top assembly of chamber 5, including the gas distribution assembly, gas boxes, and remote plasma source, are described in more detail in commonly assigned U.S. Ser. No. 10/327,209 (APPM 7816), filed Dec. 20, 2002 and entitled “BLOCKER PLATE BYPASS DESIGN TO IMPROVE CLEAN RATE AT THE EDGE OF THE CHAMBER”, which is incorporated herein by reference. Although embodiments of the invention are described with reference to the Producer® Reactor, other CVD reactors or plasma-processing chambers may also be used to practice various embodiments of the invention, such as, the DXZ® Chamber, which is also commercially available from Applied Materials, Inc. of Santa Clara, Calif. The DXZ® Chamber is disclosed in commonly assigned U.S. Pat. No. 6,364,954 B2, issued Apr. 2, 2002, which is also incorporated herein by reference.

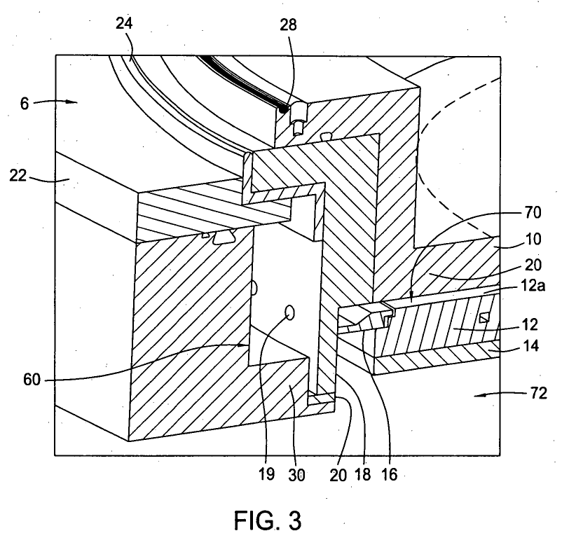

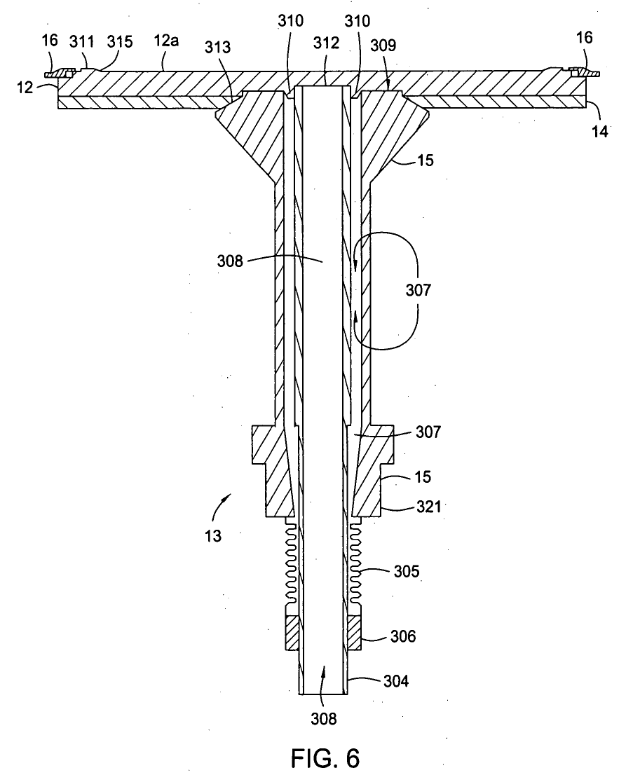

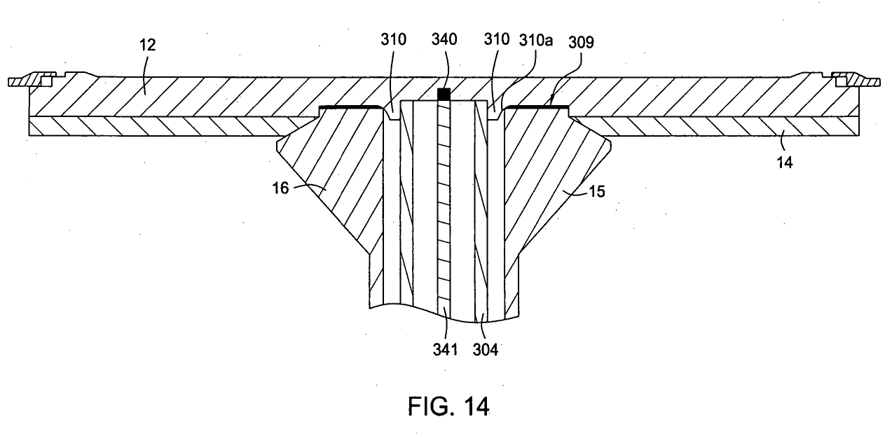

FIG. 2 illustrates a perspective and partial sectional view of plasma-processing chamber 5 of the present invention. Plasma processing chamber 5 comprises a top assembly (not shown), a lid assembly 6, a lid support 22 (shown in FIG. 3), and a lower chamber assembly 8. The top assembly includes a gas distribution assembly, one or more gas boxes and a remote plasma source, mounted on top of lid assembly 6. As shown in FIG. 3, lid assembly 6 is attached to lid support 22, which is mounted on top of lower chamber assembly 8. Lower chamber assembly 8 comprises a chamber body 30, chamber body heaters 27, a heater assembly 13, and a lift assembly 40. As shown in FIG. 2, heater assembly 13 penetrates chamber body 30 through an opening 39 in the floor of chamber body 30. Opening 39 is sealed from atmospheric pressure with a bellows (not shown for clarity). This bellows is attached in a vacuum-tight manner to the bottom of chamber body 30 and to surface 321 (see FIG. 6) of outer support shaft 15, allowing vertical motion of heater assembly 13 relative to plasma-processing chamber 5. As shown in FIG. 2, the lift assembly 40 includes a lift hoop 41 and at least three lift pins 42 and is located inside chamber body 30 and below heater pedestal 12. Heater assembly 13 comprises a heater pedestal 12, an edge ring 16, a ceramic support structure 14, an inner shaft 304 (also referred to as a riser tube), an internal heating element (not shown), a thermocouple 340 (shown in FIG. 14) and an outer support shaft 15. The use of aluminum heater pedestal 13 and ceramic support 14 combines the advantages of a standard aluminum heater (low cost and high temperature and plasma uniformity) with the high rigidity associated with a ceramic heater. Referring back to FIG. 6, outer support shaft 15 penetrates chamber body 30 through opening 39. Ceramic support structure 14 rests on outer support shaft 15, heater pedestal 12 rests on ceramic support structure 14, and edge ring 16 rests on heater pedestal 12. Thermocouple 340 (shown in FIG. 14) is attached to Heater pedestal 12 and may be used to monitor the temperature of heater pedestal 12 during substrate processing. Referring back to FIG. 6, riser tube 304 is fixed to the bottom of heater pedestal 12 and is disposed inside outer support shaft 15. Heater assembly 13 is also shown in greater detail in FIG. 6. Outer support shaft 15 and riser tube 304 form a two-walled support shaft for heater pedestal 12 and ceramic support structure 14, which allows for electrical feed-throughs into the heater pedestal at atmosphere inside the inner shaft while maintaining the rest of the volume inside the support shaft at vacuum. Such electrical feed-throughs are less prone to failure than the prior art.

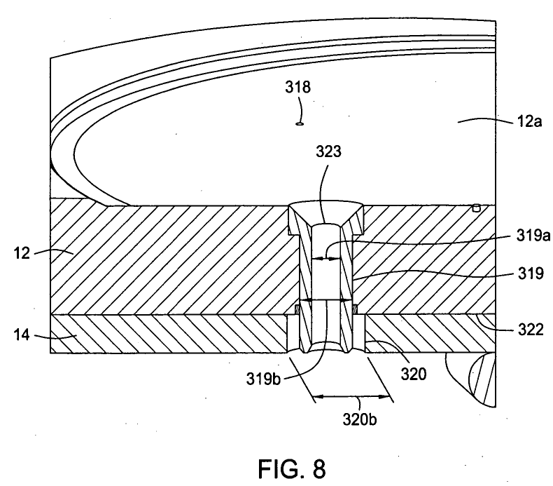

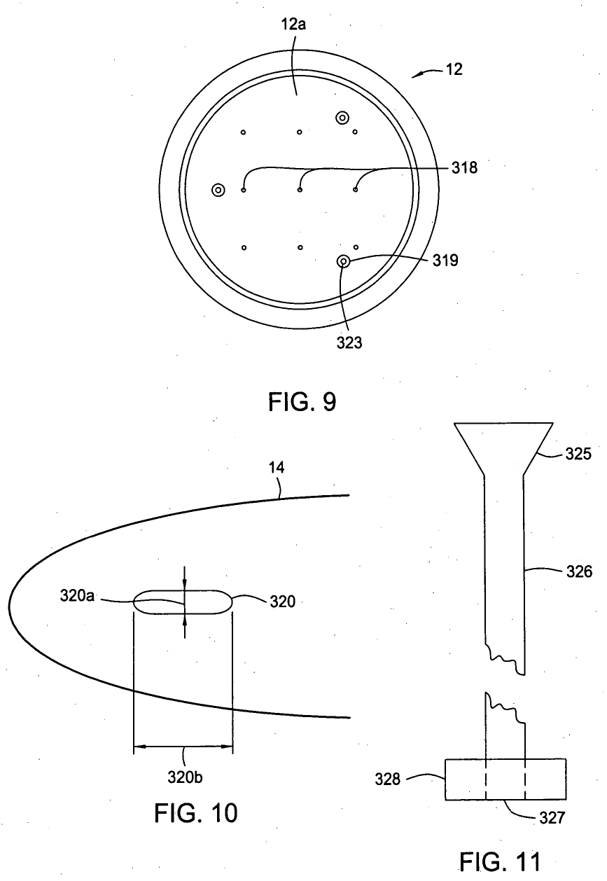

In one embodiment, the bottoms of lift pins 42 are fixed to lift hoop 41. In another embodiment, the lift pins 42 are not fixed to lift hoop 41, but instead hang down from heater pedestal 12. In this embodiment, lift pins 42 are also not fixed to heater pedestal 12 and rest inside lift pin through-holes 323 (see FIGS. 8 and 9) of diameter 319a (see FIG. 8). The lift pins 42 are supported in through holes 323 by wedge-shaped lift pin tips 325 (see FIG. 11). Lift pin tips 325 are larger in diameter than through-hole diameter 319a and lift pin shafts 326 (see FIG. 11) are smaller in diameter than through-hole diameter 319a. The bottom ends 327 of lift pins 42 hang below heater pedestal 12 and ceramic support 14 and contact lift hoop 41 when heater assembly 13 is lowered for transferring the substrate to a robot blade. Lift pin tips 325 do not protrude above the plane of substrate receiving surface 12a until lift pins 42 are contacted by lift hoop 41. This embodiment allows the diameter of lift pin through-holes 323 in heater pedestal 12 to be as small as possible. Due to thermal expansion of heater pedestal 12 during processing, a large range of motion can take place between through-holes 323 and lift pins 42 if lift pins 42 are fixed to hoop lift 41. This requires through-holes 323 to be large in diameter to accommodate the relative motion between a lift pin 42 and its respective through-hole 323. In one embodiment, a weight 328 is attached to the bottom of each lift pin 42 to move the center of gravity of the lift pins 42 to a point below heater pedestal 12 when heater pedestal 12 has moved to a position at the bottom lower chamber 72 and the substrate is resting on the lift pins 42.

As shown in FIG. 3, the lid assembly 6 comprises a showerhead 10, a heating element 28, an isolator 18, a leak-by ring 20, a thermal isolator 24, a lid support 22 and a top assembly (not shown). In one embodiment the heating element 28 is a resistive heating element mounted to the showerhead 10 having a power rating from about 100 W and about 1000 W, and preferably about 400 W. Lid support 22 is mounted in a vacuum-tight manner to the top of chamber body 30 and supports the rest of the lid assembly 6 components. The thermal isolator 24 is mounted between lid support 22 and isolator 18 and forms a vacuum seal between these two components. Isolator 18 electrically isolates lid assembly 6 and the top assembly when plasma is struck in chamber 5. Isolator 18 is manufactured from a material such as a strong, vacuum compatible, dielectric material, for example a ceramic like alumina. In one embodiment thermal isolator 24 minimizes the heat conduction from isolator 18 to lid support 22, minimizing thermal gradients inside isolator 18. High thermal gradients present in ceramic components can result in cracking—particularly when the ceramic component is under load. The added thermal insulation provided by thermal isolator 24 minimizes thermal gradients inside isolator 18, reducing the possibility of isolator 18 cracking. The thermal isolator 24 is made from a material such as a vacuum-compatible plastic material (e.g., PTFE, Teflon, etc.).

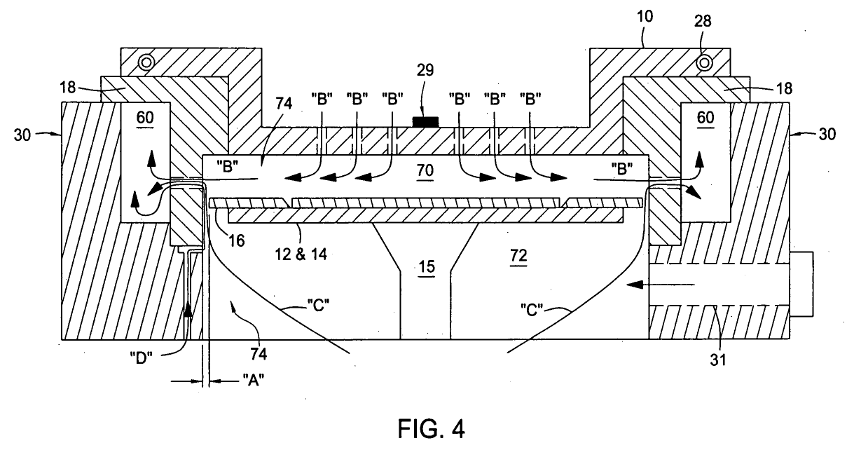

As shown in FIG. 3, isolator 18, lid support 22, leak-by ring 20 and the chamber body 30 form a vacuum plenum 60 which is connected to a vacuum pump (not shown) external to plasma processing chamber 5. The vacuum plenum 60 is connected to the vacuum region 74 (shown in FIG. 4) through a plurality of vacuum ports 19 in the isolator 18. Vacuum region 74 generally comprises a processing region 70 (shown in FIGS. 3 and 4) and a lower chamber 72 (shown in FIGS. 2 and 3) when heater assembly 13 is in the process position (as shown in FIGS. 1, 3 and 4). Vacuum ports 19 are arranged around the perimeter of processing region 70 to provide uniform removal of process gases from processing region 70. The lower chamber 72 is generally defined as the region below heater assembly 13 when it is up in the process position (as shown in FIGS. 2 and 3) and inside chamber body 30.

A substrate is transferred into plasma processing chamber 5 by use of a robot (not shown) mounted in the mainframe. The process of transferring a substrate into plasma processing chamber 5 typically requires the following steps: heater assembly 13 is moved to a position at the bottom of lower chamber 72 below slit valve 31, the robot transfers the substrate into chamber 5 through the slit valve 31 with the substrate resting on a robot blade (not shown), the substrate is lifted-off the robot blade by use of lift assembly 40, the robot retracts from plasma processing chamber 5, heater assembly 13 lifts the substrate off the lift pins 42 and moves to a process position near showerhead 10 (forming the processing region 70), the chamber process steps are completed on the substrate, heater assembly 13 is lowered to a bottom position (which deposits the substrate on the lift pins 42), the robot extends into chamber 5, lift assembly 40 moves downward to deposit the substrate onto the robot blade and then the robot retracts from plasma processing chamber 5. In one embodiment, the lift pins 42 are not fixed to hoop lift 41 and instead rest in the lift pin through-holes 323 during substrate processing as described above. In this embodiment, heater assembly 13 lifts the substrate off the lift pins 42 and also lifts the lift pins 42 off of lift hoop 41 when moving upward to a process position near showerhead 10. When the chamber process steps are completed on the substrate and heater assembly 13 is lowered to a bottom position, the lift pins 42 contact lift hoop 41 and stop moving downward with heater pedestal 12. As heater pedestal 12 continues to move downward to the bottom position, the substrate is then deposited on the lift pins 42, which are resting on hoop lift 41.

FIG. 4 illustrates a schematic cross-sectional view of the plasma-processing chamber 5 during substrate processing. When a substrate is processed in chamber 5, process gases are flowed into process region 70 and deposition of material takes place on the surface of the substrate until the desired film is formed. Optionally, the deposition process may be enhanced by forming a plasma of the process gases within the chamber and/or by heating the substrate. The substrate is typically heated to the desired process temperature by heater pedestal 12. In one embodiment, heater pedestal 12 is operated at a process temperature of about 400 to about 480 C. At intervals an in-situ clean is performed on process chamber 5 to remove deposits of process byproduct material from all surfaces exposed to processing region 70, including faceplate 10, isolator 18, heater pedestal 12 and edge ring 16, as well as surfaces in the lower chamber 72. The length of the interval between in-situ cleans is defined by what type of material is being deposited, how much material is being deposited and the sensitivity of substrates to particle contamination. The methods and apparatus for performing plasma-enhanced chemical vapor deposition (PE-CVD) and for performing an in-situ clean of a plasma-processing chamber are fully described in the commonly assigned U.S. Ser. No. 10/327,209 (APPM 7816), filed Dec. 20, 2002 and entitled “BLOCKER PLATE BYPASS DESIGN TO IMPROVE CLEAN RATE AT THE EDGE OF THE CHAMBER”, which is incorporated herein by reference. FIG. 4 depicts the process or cleaning gas flow path “B” from an external source (not shown), to a showerhead region enclosed by the top assembly (not shown) and showerhead 10, through showerhead 10 into process region 70, then through vacuum ports 19, into vacuum plenum 60 and then out of plasma-processing chamber 5 to a remote vacuum pump (not shown).

In one embodiment, heater pedestal 12 contains a heat generating device or devices that can heat a substrate resting or mounted on the substrate receiving surface 12a (see FIG. 6). Heater pedestal 12 can be made from a material such as a metallic or ceramic material with the heat generating devices embedded or contained therein.

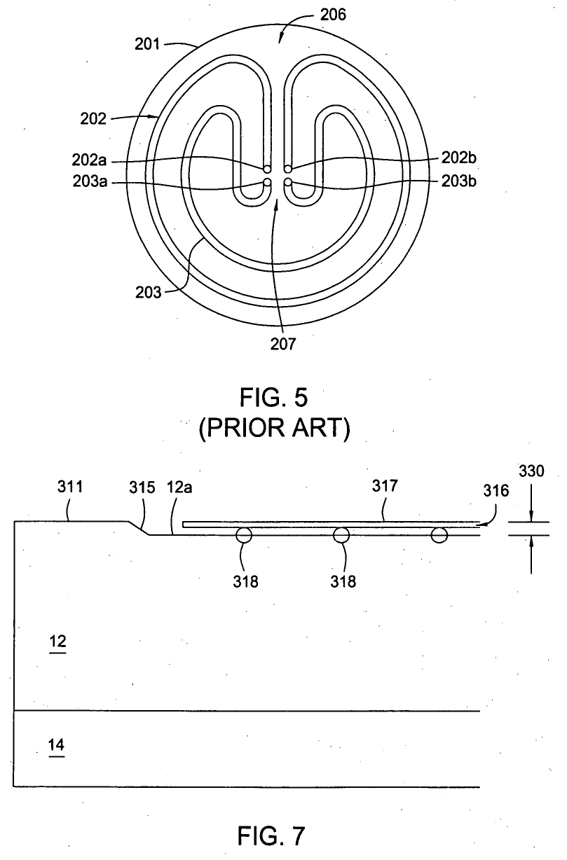

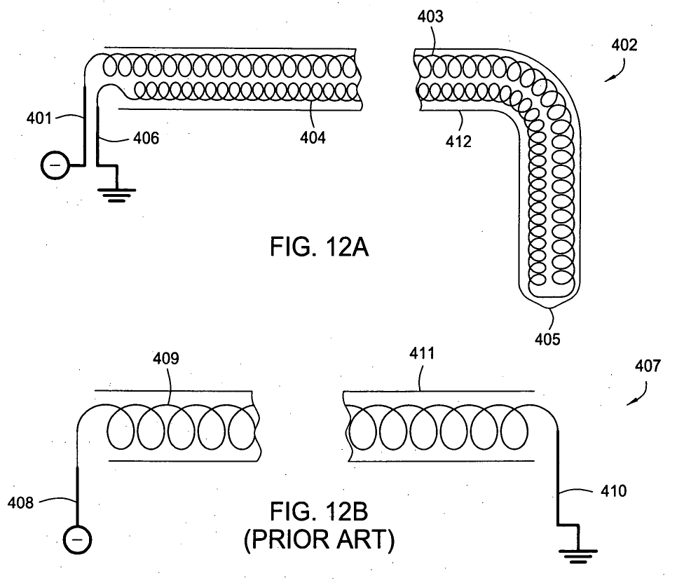

In one embodiment, heater pedestal 12 uses an electrical resistance heating element (not shown) to heat substrates processed in chamber 5. In this embodiment, only a single electrical heating element is arranged inside heater pedestal 12. The electrical heating element is a dual filament tubular heating element, i.e., the heating element consists of two parallel filaments that are packaged together in a single sheath, electrically isolated from each other and electrically connected at one end, creating a single, two-filament heating element. Hence, the electrical connections for the tubular heating element are both at one end of the heating element. This is schematically illustrated in FIG. 12a. Large diameter wire 401 of electrical heating element 402 enters heater pedestal 12 through an electrical feed-through (not shown). Filament 403 and 404 are both contained inside protective sheath 412 but are electrically isolated from each other. Filament 403 is electrically connected to large diameter wire 401 at one end and to filament 404 at end point 405 of heating element 402. Filament 404 connects to large diameter wire 406, which exits heater pedestal 12 through the same feed-through used by wire 401. Heating element 402 is arranged inside heater pedestal 12 with a single point of mechanical connection to heater pedestal 12—i.e., at the electrical feed-through for wires 401 and 406. End point 405 is left unconstrained inside heater pedestal 12. Because only one end of heating element 402 is mechanically constrained, the torsional force on heating element 402 at wires 401 and 406 is greatly reduced during heating and cooling of heating element 402 compared to the prior art. End point 405 is free to move in response to the expansion and contraction of heating element 402. Therefore, heating element 402 experiences much fewer failures than typical heating elements in this application, for example, the heating elements 202 and 203, shown in FIG. 5. Because heating elements 202 and 203 are fixed at each end, they are not free to move in response to thermal expansion and contraction and, therefore, undergo significant torsion each time they are cycled on and off. In contrast to heating element 402, the conventional electrical heating element 407 (as shown in FIG. 12b) only contains a single filament 409 inside protective sheath 411 and therefore must have an electrical connection at each end of heating element 407. Large diameter wire 408 enters heater pedestal 12 through an electrical feed-through (not shown). Heating element 407 is arranged inside heater pedestal 12 in a manner similar to that illustrated for heating elements 202 and 203 inside a typical prior art heater pedestal 201 (see FIG. 5). Referring back to FIG. 12b, filament 409 inside heating element 407 is electrically connected to large diameter wire 408 at one end of heating element 407 and to large diameter wire 410 at the opposite end of heating element 407. Wire 410 exits heater pedestal 12 though a second electrical feed-through. Heating element 407 requires two electrical feed-throughs into heater pedestal 12, one feed-through for wire 408 and one for wire 410.

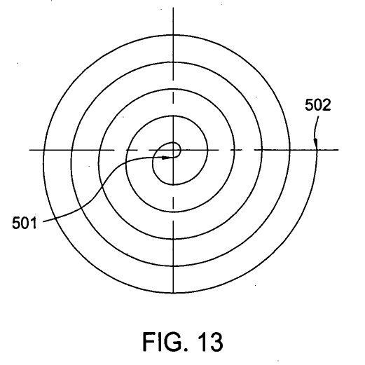

In one embodiment of heater pedestal 12, the internal heating element is a dual filament element (not shown) and is arranged inside heater pedestal 12 in the form of an Archimedes spiral. The Archimedes spiral arrangement is used to ensure uniform heat distribution across the entire heater pedestal 12 when processing substrates. An Archimedes spiral is described by the equation r=aθ, where a is a constant used to define the “tightness” of the spiral. An example of an Archimedes spiral is shown in FIG. 13. All electrical connections for the internal heating element enter and exit heater pedestal 12 via a single electrical feed-through (not shown), located at the center of heater pedestal 12. The center of the Archimedes spiral 501 in FIG. 13 corresponds to wires 401 and 406 in FIG. 12 and the end of the spiral 502 in FIG. 13 corresponds to endpoint 405 of heating element 402. The Archimedes spiral arrangement for the internal heating element of heater pedestal 12 eliminates cold spots by reducing the number of electrical feeds from two or four to only one and by providing a more uniform arrangement of the heating element. With more uniform heat distribution in heater pedestal 12, the potential for warping of heater pedestal 12 is reduced and substrates are heated more evenly during processing. In one embodiment, the through-holes in heater pedestal 12 for lift pins 42 are not located on the same bolt circle, i.e., they are not displaced radially from the center point of heater pedestal 12 an identical distance. In embodiments in which a lift pin 42a (see FIG. 2) is one of the plurality of lift pins 42 located opposite slit valve opening 31, lift pin 42a and its associated through-hole is located farther from the center point of heater pedestal 12 than the other lift pins 42. This asymmetrical arrangement of the lift pin through-holes avoids interference with the arrangement of the internal heating element of heater pedestal 12 in an unmodified Archimedes spiral configuration, ensuring even heating of substrates. Additionally, the placement of lift pin 42a farther from slit valve opening 31 can improve the reliability of transferring substrates into and out of chamber 5 by allowing for a larger robot blade. A larger robot blade can accommodate optical sensors with greater surface area, which more reliably detect the presence or absence of a substrate on the robot blade.

To accommodate the significant thermal expansion of heater pedestal 12 that takes place at the high temperatures present when operating, heater pedestal 12 is neither fixed to nor constrained by outer support shaft 15 and instead rests or “floats” on outer support shaft 15. This prevents the warping of heater pedestal 12 that would occur if it were fixed to outer support shaft 15, particularly when outer support shaft 15 consists of a material of lower thermal expansion than heater pedestal 12, such as alumina. In one embodiment, the annular feature 309 disposed on the top end of outer support shaft 15 is configured to mate with pedestal alignment features 310 located on the bottom of heater pedestal 12 in order to precisely center heater pedestal 12 relative to outer support shaft 15 and chamber 5 (see FIG. 6 and FIG. 14). Pedestal alignment features 310 are configured to allow thermal expansion of heater pedestal 12 using an angled or curved surface 310a (see FIG. 14) to contact outer support shaft 15. Hence, heater pedestal 12 is precisely centered in chamber 5 without being fixed to other chamber elements that would cause warping at process temperatures. In one embodiment, outer support shaft 15 is adapted to define the rotational position of heater pedestal 12 with respect to chamber 5, using an alignment feature—for example a radial tab—that mates with a corresponding alignment feature on heater pedestal 12—for example a radial slot. In another embodiment, outer support shaft 15 is instead adapted to fix ceramic support 14 rotationally with respect to chamber 5, using an alignment feature-for example a radial tab—that mates with a corresponding alignment feature on ceramic support 14—for example a radial slot. Hence, the rotational alignment of heater pedestal 12 is precisely defined with respect to chamber 5 without subjecting heater pedestal 12 to warping when at process temperature.

In one embodiment, heater pedestal 12 is not fixed to ceramic support 14 and is rotationally positioned relative to ceramic support 14 by alignment features 319, shown in FIG. 8, adapted to project below the bottom surface 322 of heater pedestal 12. Alignment features 319 mate with corresponding alignment slots 320 disposed in ceramic support 14. Alignment slots 320 are adapted to precisely define the rotational position of heater pedestal 12 with respect to ceramic support 14 but to allow unconstrained movement of alignment features 319 radially inward. Radial movement of alignment features 319 relative to alignment slots 320 occurs during substrate processing because the thermal expansion of heater pedestal 12 is greater than that experienced by ceramic support 14. This radial movement of alignment features 319 is not constrained by alignment slots 320 because alignment slots 320 are radially oriented slots of length 320b, where length 320b is significantly greater than outer diameter 319b of alignment feature 319 (see FIGS. 8 and 10). But slot width 320a is sized to closely match outer diameter 319b of alignment feature 319. FIG. 10 illustrates the relationship of slot width 320a and slot length 320b as well as the radial orientation of a slot 320 in ceramic support 14. Hence, the rotational relationship of heater pedestal 12 and ceramic support 14 is precisely defined without warping heater pedestal 12 due to thermal expansion and contraction. In one embodiment, alignment features 319 are ceramic pins embedded or pressed into heater pedestal 12 and project below bottom surface 322 of heater pedestal 12 in order to mate with alignment slots 320 in ceramic support 14 (see FIG. 8). In another embodiment, alignment features 319 serve the dual purpose of rotationally aligning heater pedestal 12 and ceramic support 14 and acting as through-holes 323 for each of the lift pins 42. In this embodiment, alignment features 319 are also hollow cylinders with center holes of the necessary diameter 319a to accommodate lift pins 42 and are located in heater pedestal 12 as necessary to accommodate each and every lift pin 42 (see FIGS. 8 and 9).

Referring to FIG. 7, substrate receiving surface 12a is over-sized relative to the outer dimensions of substrates being processed in processing chamber 5 to allow for thermal expansion and contraction of heater pedestal 12. In one embodiment, substrate receiving surface 12a is modified by swaging a plurality of small sapphire balls 318 into its surface (see FIG. 7). The sapphire balls 318 are uniformly distributed over substrate receiving surface 12a, are of equal diameter, and act as contact points on which a substrate 316 rests during processing in processing chamber 5. The number of sapphire balls 318 swaged into surface 12a can be as few as three but preferably as many as nine (see FIG. 9 for one embodiment of the distribution of sapphire balls 318 on substrate receiving surface 12a). The contact points formed by the sapphire balls 318 prevent substrate 316 from directly contacting substrate receiving surface 12a, for uniform heating, and maintain the top surface of the substrate 317 co-linear with peripheral outer surface 311 of heater pedestal 12, for uniform processing of the substrate (see FIG. 7). The diameter of the sapphire balls used for this application is determined by how deeply they are swaged into surface 12a, the distance 330 between parallel surfaces 12a and 311 of heating pedestal 12, and the thickness of substrate 317. To prevent the creation of ‘virtual leaks” (i.e., trapped volumes inside a vacuum chamber that greatly increase pump-down time), sapphire balls 318 are swaged into substrate receiving surface 12a in such a manner that no dead volume is present behind them.

Ceramic support 14 is fabricated from a material that is compatible with the plasma processing gas and remains rigid at process temperature, for example, a ceramic such as alumina. Ceramic support 14 is an annular structural component used to support heater pedestal 12 to prevent droop and/or warping caused by stress relaxation when heater pedestal 12 is at process temperature. By eliminating droop of heater pedestal 12, ceramic support 14 allows the use of an all aluminum pedestal design for heater pedestal 12, which has higher temperature uniformity, higher plasma uniformity, higher reliability of internal electrical connections and lower cost than other pedestal designs. In one embodiment, the inner radial surface 313 (see FIG. 6) of ceramic support 14 that mates with and rests on outer support shaft 15 is configured to allow for thermal expansion when heater pedestal 12 is in operation. For example, the inner radial surface 313 of ceramic support 14 is neither fixed to nor constrained by outer support shaft 15 and instead is resting or “floating” on outer support shaft 15. Additionally, ceramic support 14 possesses radial alignment slots 320 that align with alignment features 319, which rotationally align heater pedestal 12 and ceramic support 14 in a precise fashion and allow unconstrained thermal expansion and contraction of heater pedestal 12 relative to ceramic support 14 (see FIG. 8).

Outer support shaft 15 is a structural support for heater pedestal 12 and ceramic support 14. A lift assembly (not shown), attached to outer support shaft 15, is designed to raise and lower heater assembly 13 to a process position (shown in FIG. 2, FIG. 3 and FIG. 4) and to a transfer position (not shown) below the slit valve opening 31. A bellows (not shown) is used to seal the exterior surface of the outer support shaft 15 to the chamber body 30. Outer support shaft 15 has a hollow center, which is vented to the interior of plasma-processing chamber 5. In one embodiment the outer support shaft 15 is made from a material that minimizes the conduction of heat from the heater pedestal 12 to the chamber body 30 or other chamber components, such as a ceramic material of relatively high mechanical strength at the temperatures found in chamber 5, such as alumina. The use of such a material for outer support shaft 15 greatly reduces the stresses caused by thermal expansion and contraction of outer support shaft 15 and the associated warping of heater pedestal 12 because of these stresses. Riser tube 304 is disposed inside of and parallel to outer support shaft 15. Riser tube 304 is fixed to the bottom of heater pedestal 12 in a vacuum-tight manner, for example brazed or welded. In one embodiment, the location 312 at which riser tube 304 is fixed to heater pedestal 12 is at the center of heater pedestal 12, inside alignment feature 310 (as shown in FIG. 6). The region 307 between heater pedestal 15 and riser tube 304 is vented to the interior of plasma processing chamber 5 and therefore is at vacuum when chamber 5 is operational. The region 308 inside riser tube 304 is vented to atmospheric pressure at all times, allowing all electrical feed-throughs into the bottom of heater pedestal 12 to be made with connections at atmosphere. With all electrical connections to heater pedestal 12 at atmosphere, the use of a high-temperature, vacuum compatible seal is not required. This extends the lifetime of heater assembly 13, improves the reliability of heater assembly 13 and its internal electrical connections and simplifies installation and assembly of heater assembly 13 and heater pedestal 12. Electrical connections to heater pedestal 12 may include power for electrical heating elements, thermocouple wiring, and RF bias wires. In one embodiment, heater pedestal 12, a heating element (not shown) disposed inside of heater pedestal 12, a thermocouple 340 (shown in FIG. 14) attached to heater pedestal 12, a thermocouple tube 341 (shown in FIG. 14) disposed inside riser tube 304 and riser tube 304 are brazed together as a single electrical assembly prior to installation into chamber 5.

The exposure of the bottom of heater pedestal 12 to the atmospheric pressure in region 308 results in an upward force on the center of heater pedestal 12 when chamber 5 is at vacuum (see FIG. 6). This upward force can warp heater pedestal 12 when operating at process temperatures. To counteract such an upward force, an equal downward spring force is applied to riser tube 304. Therefore, a region of heater pedestal 12 can be exposed to atmospheric pressure without the risk of warping when at process temperature. In one embodiment a conventional spring is used to apply the downward force on riser tube 304. In another embodiment, the downward spring force on riser tube 304 is produced by means of a vacuum bellows 305, which is fixed with clamp 306 to riser tube 304 in a compressed state. Bellows 305 (shown in FIG. 6) is distinct from the bellows (not shown) that is attached to the bottom of chamber body 30 and to surface 321 (see FIG. 6) of outer support shaft 15, the latter bellows allowing vertical motion of heater assembly 13 relative to plasma-processing chamber 5. The force required to compress vacuum bellows 305 pushes downward on clamp 306, which in turns pushes downward on riser tube 304. The downward force applied to riser tube 304 can be increased or decreased by adjusting the compressive displacement of vacuum bellows 305 during assembly. In one embodiment, vacuum bellows 305 is attached to outer support shaft 15 (as shown in FIG. 6) in a vacuum-tight manner, such as with an O-ring (not shown) and O-ring groove (not shown). In this embodiment, vacuum bellows 305 is also attached to clamp 306 in a similar vacuum-tight manner. Also in this embodiment, a vacuum sealing material (not shown), such as a vacuum-compatible polymer or plastic, is incorporated into clamp 306 and seals vacuum region 307 from atmospheric pressure. Hence, vacuum region 307 extends down the outer surface of riser tube 304, inside vacuum bellows 305, to the sealing surface of clamp 306.

In one embodiment, edge ring 16 rests on heater pedestal 12 (see FIG. 2 and FIG. 3) and is fabricated from a material that is compatible with the plasma processing gas and has a relatively small coefficient of thermal expansion, such as a ceramic material, for example alumina. When heater assembly 12 is in the process position (as shown in FIGS. 2 and 3), a gap “A” between edge ring 16 and isolator 18 is purposely made small enough to minimize leakage of the process gases and plasma into the lower chamber 72 (see FIG. 4). It is important that the material of edge ring 16 is subject to minimal thermal expansion, since the outer diameter of edge ring 16 defines the size of gap “A” (see FIG. 4).

By use of a purge gas injected into the lower chamber 72, a pressure differential can be created between the lower chamber 72 and the process region 70, thus further preventing the leakage of the process gas into lower chamber. The gap “A” between the edge ring 16 and the isolator 18 may be between about 0.010 and about 0.060 inches, and preferably between about 0.020 and about 0.040 inches. The purge gas can be injected from purge ports in the lower chamber such as upper port 36 and lower port 34. In one embodiment the purge gas is an inert gas such as helium or argon. In another embodiment, the flow of the purge gas is sufficient to maintain the pressure of lower chamber 72 at a higher pressure than the pressure in process region 70 during substrate processing. By preventing the leakage of the plasma and the process gases into the lower chamber 72 the amount of shielding required to prevent attack of the lower chamber components will be greatly reduced, thus reducing the consumable cost and in-situ clean time after a number of substrates have been processed in the plasma processing chamber 5. Less shielding in vacuum region 74 of the plasma processing chamber 5 also reduces chamber pump down time. By preventing the leakage of the plasma and the process gases into the lower chamber 72, attack of system components such as the slit valve door (not shown) can be minimized thus reducing the system maintenance downtime. By use of the gap “A” and the purge gas, less process gas is required to run the desired process, since the amount of process gas leaking out of the process region is reduced, thus reducing the consumption of costly and often hazardous chemicals. In one embodiment the purge gas flow path is schematically shown by line ”C” moving from the lower chamber 72 through the gap “A”, through the vacuum port 19 into the vacuum plenum and then out to the vacuum pump. In another embodiment the purge gas flow path “D” may be from upper port 36 through the vacuum port 19 into the vacuum plenum and then out to the vacuum pump.

In one embodiment of the invention, the heating element 28, which is used to heat the showerhead 10 and isolator 18, may be used to reduce the generation of particles in chamber 5. When substrates are not being processed in chamber 5, showerhead 10 and isolator 18 can be prevented from cooling by operating heating element 28. The cooling of showerhead 10 and isolator 18 is the type of oscillation in temperature that encourages flaking of deposited process byproducts, contaminating substrates processing in chamber 5 with particles. Oscillations in the temperature of showerhead 10 and isolator 18 are minimized when these components are maintained at a relatively high temperature, ideally about 200 degrees C., when no substrates are being processed in chamber 5. This is because during substrate processing, processes using higher plasma powers can easily heat showerhead 10 and isolator 18 to at least 200 degrees C. Using heating element 28 to maintain these components at temperatures higher than 200 degrees C. is possible, but O-ring degradation occurs at temperatures >204 degrees C. The power required for heating element 228 to bring showerhead 10 and isolator 18 to 200 degrees C. is application specific, for example, the 300 mm silane oxide process requires operating heating element 228 at 500 W. In one embodiment, a temperature sensor, such as a thermocouple 29, attached to showerhead 10 controls heating element 28.

In one embodiment of the invention, temperature oscillations of showerhead 10 and isolator 18 can be reduced by cooling these components when substrates are processed in chamber 5 and plasma energy heats them beyond 200 degrees C. In one embodiment, external air-cooling is used and is controlled by a temperature sensor, such as thermocouple 29, attached to showerhead 10. When the temperature of showerhead 10 is measured above a setpoint temperature, ideally about 200 degrees C., fans external to chamber 5 are turned on and direct cooling air over the exposed surfaces of lid assembly 6. In another embodiment, a different cooling method is used, for example water cooling.

In one embodiment of the invention, the inner surfaces of chamber body 30 are maintained at an elevated temperature by one or more chamber body heaters 27, mounted to or embedded in the walls of chamber body 30 (see FIGS. 1 and 2). In one embodiment, the chamber walls are maintained at a temperature equal to or greater than 160 degrees C. at all times, regardless of whether substrates are being processed in chamber 5. This greatly discourages particle generation from process byproducts deposited on the internal walls of lower chamber 72.

While the foregoing is directed to embodiments of the present invention, other and further embodiments of the invention may be devised without departing from the basic scope thereof, and the scope thereof is determined by the claims that follow.

1. A plasma processing chamber having top, bottom and side walls, comprising:
a process region formed between the top wall, the side walls and a substrate support spaced above the bottom wall;
at least one vacuum port disposed in a side wall and in communication with the process region;
a gap formed between the substrate support and the side wall; and
a purge gas source positioned to provide a purge gas through the gap into the process region.

2. The apparatus of claim 1, wherein the gap formed between the substrate support and the side wall is between 0.010 and 0.060 inches.

3. The apparatus of claim 1, wherein the gap formed between the substrate support and the side wall is between 0.020 and 0.040 inches.

4. The apparatus of claim 1, further comprising a plasma processing heater assembly, wherein the heater assembly comprises a support shaft, a ceramic heater support structure disposed on the support shaft, and an aluminum heater pedestal disposed on the ceramic heater support structure.

5. A plasma processing chamber having top, bottom and side walls, comprising:
a process region formed between the top wall, the side walls and a substrate support spaced above the bottom wall;
a plasma processing heater assembly, wherein the heater assembly comprises a support shaft, a ceramic heater support structure disposed on the support shaft, and an aluminum heater pedestal disposed on the ceramic heater support structure.

6. A plasma processing chamber, comprising:
a chamber body including chamber walls, a chamber floor, and a lid support;
a lid assembly on the lid support;
a processing region formed between the lid assembly and a substrate support;
a lower chamber region formed by the floor and walls of the plasma processing chamber and the bottom of the substrate support when the substrate support is in process position;
a cooling system adapted to prevent the lid assembly temperature from rising above an optimal setpoint when plasma processing takes place in said chamber;
a heating system adapted to prevent the lid assembly temperature from dropping below an optimal setpoint when plasma processing does not take place in the plasma processing chamber;
a further heating system adapted to heat the walls of the lower chamber region; and
a thermal isolator disposed between the lid assembly and the lid support.

7. The apparatus of claim 6, wherein the cooling system is fan-based and the fans are controlled by a thermocouple disposed on the lid assembly.

8. The apparatus of claim 6, wherein the heating system comprises one or more electrical resistance heaters embedded peripherally in the lid assembly and said heaters are controlled by a thermocouple disposed on lid assembly.

9. The apparatus of claim 6, wherein the further heating, system comprises one or more electric resistance heaters embedded inside the walls of said chamber's lower chamber region.

10. The apparatus of claim 6, wherein the thermal isolator consists of a vacuum compatible polymeric material.

11. A plasma processing heater assembly, comprising:
a support shaft;
a ceramic heater support structure disposed on the support shaft; and
an aluminum heater pedestal disposed on the ceramic heater support structure.

12. The apparatus of claim 11, wherein the aluminum heater pedestal is not fixed to the ceramic heater support structure.

13. The apparatus of claim 12, wherein said shaft and pedestal possess mutually mating slotted features adapted to rotationally align said pedestal about said shaft.

14. The apparatus of claim 11, wherein the support shaft is a ceramic material.

15. The apparatus of claim 14, wherein the ceramic is alumina.

16. A plasma processing heater pedestal, comprising:
an aluminum pedestal adapted to contain an electrical heating element; and
an electrical heating element disposed inside the aluminum pedestal, wherein electrical connections to said heating element are fed into and out of the pedestal through a single penetration.

17. The apparatus of claim 16, wherein said heating element is arranged to describe an Archimedes' spiral inside the aluminum pedestal.

18. A plasma processing heater assembly, comprising:
an aluminum pedestal adapted to contain an electrical heating element, the pedestal configured to form one side of a plasma processing region;
an electrical heating element inside the pedestal;
a temperature sensor inside the pedestal;
a double-walled support shaft, the inner wall of said shaft being fixed in a vacuum tight manner to a side of said pedestal not exposed to said processing region;
a volume between the outer and inner walls of said shaft, the volume being vented to the plasma processing region;
a further volume disposed inside the inner wall of said shaft, the further volume being vented to atmospheric pressure; and
electrical feed-throughs for the heating element and the temperature sensor, said feed-throughs being disposed on the side of said pedestal not exposed to said processing region and further disposed inside the further volume at atmospheric pressure.

19. The apparatus of claim 18, wherein the electrical connections to said heating element are fed into and out of the pedestal through a single penetration.

20. The apparatus of claim 19, wherein the heating element is arranged to describe an Archimedes’ spiral inside the aluminum pedestal.

21. The apparatus of claim 18, further comprising a spring tensioner exerting a force on the inner wall of the double-walled support shaft equal and opposite to a force resulting from vacuum being on one side of the aluminum pedestal and atmospheric pressure on the other.

22. The apparatus of claim 21, wherein the spring tensioner is also a bellows used to isolate vacuum inside the outer wall of said support shaft from atmospheric pressure.

23. A plasma processing substrate support, comprising:
an pedestal configured to support a substrate during plasma processing;
a plurality of sapphire balls of equal diameter swaged into the face of the pedestal; and
an absence of any dead volume between said balls and the face of the pedestal.

24. The apparatus of claim 23 wherein the pedestal further comprises:
a plurality of sapphire balls of equal diameter swaged into the face of the pedestal; and
an absence of any dead volume between said balls and the face of the pedestal.

25. A method of preventing process gas in a processing region in a plasma-processing chamber from flowing into a non-processing region of the chamber, comprising:
introducing a purge gas into the non-processing region of said chamber at a flow rate sufficient to pressurize the non-processing region relative to the processing region.

26. The method of claim 25, wherein the purge gas is an inert gas, such as argon, helium, or nitrogen.

27. A method of preventing failure of a substrate support heating element, comprising:
utilizing a dual filament tubular heating element inside a substrate support;
feeding the conductors for the heating element into the substrate support through a single aperture; and
constraining the heating element inside the substrate support only at one end of the heating element.

28. A method of maintaining uniformity of substrate heating, comprising:
utilizing a dual filament tubular heating element inside a substrate support;
feeding the conductors for the heating element into the substrate support through a single aperture at the center of the substrate support; and
arranging the heating element inside the substrate support in the form of an Archimedes spiral.

29. A method of preventing particle generation from surfaces in a plasma-processing chamber, comprising:
cooling the lid assembly of the chamber when the temperature of the lid assembly is measured to be above about 200 degrees C.;
heating the lid assembly of the chamber when the temperature of the lid assembly is measured to be below about 195 degrees C.; and
minimizing heat transfer to and from the lid assembly with a thermal isolator.

30. The method of claim 29, wherein cooling the lid assembly comprises air cooling with fans controlled by a temperature sensor disposed on the lid assembly.

31. The method of claim 27, wherein heating the lid assembly comprises heating with an electrical heating element embedded in the lid assembly and controlled by a temperature sensor disposed on the lid assembly.

32. The method of claim 27, wherein the power of the heating element is between about 100 W and about 1000 W.

33. A method of preventing particle generation from surfaces in a non-process region of a plasma-processing chamber, comprising:
maintaining all walls of said chamber at a temperature greater than about 160 degrees C. continuously.
